(19) United States
(12) Patent Application Publication
(10) Pub. No.: US 2016/0233861 A1
(43) Pub. Date: Aug. 11, 2016

(54) KEYBOARD DEVICE

(71) Applicant: Primax Electronics Ltd., Taipei (TW)

(72) Inventor: WEI-YUNG HUANG, Taipei (TW)

(21) Appl. No.: 14/691,141

(22) Filed: Apr. 20, 2015

(30) Foreign Application Priority Data
Feb. 6, 2015 (TW) 104104065

(51) Int. Cl. H03K 17/967

(52) U.S. Cl. CPC H03K 17/967

(57) ABSTRACT

A keyboard device includes a base plate, a circuit board and plural keys. Each key includes a keycap, a scissors member, a restoring element and a sensor. The scissors member is connected with the keycap and the base plate. The restoring element is arranged between the keycap and the base plate and electrically connected with the circuit board. When the restoring element receives electricity, the restoring element is subjected to deformation and the keycap is correspondingly moved away from the base plate. When the keycap is depressed and close to the base plate, the restoring element is pressed by the keycap to trigger the sensor to generate the key signal. When the keycap is no longer depressed, the keycap is driven by the restoring element so as to be moved away from the base plate.

### FIELD OF THE INVENTION

The present invention relates to a keyboard device, and more particularly to a keyboard device with a restoring element, wherein the restoring element is subjected to deformation when receiving electricity.

### BACKGROUND OF THE INVENTION

As known, a keyboard device can provide an intuitional feedback-imparting interface for allowing the user to input signals to an electronic device in a simple manner. Even if most electronic devices are equipped with touch screens and virtual keyboards are shown on the touch screens for allowing users to input signals, physical keyboard are still frequently used by most users because the hand feel of touching the touch screen is lower than the tactile feedback of pressing the physical keyboard and the possibility of erroneously touching other keys of the touch screen is very high.

FIG. 1 is a schematic view illustrating a conventional keyboard device. As shown in FIG. 1, the conventional keyboard device 10 comprises plural keys 11, a circuit board 12 and a base plate 13. Each of the plural keys 11 comprises a keycap 111, a scissors member 112 and a rubbery elastomer 113. The keys 11 are disposed on the circuit board 12. The circuit board 12 is disposed on the base plate 13. In particular, the scissors member 112 is arranged between the keycap 111 and the rubbery elastomer 113 for connecting the keycap 111 and the base plate 13. The rubbery elastomer 113 is disposed on the circuit board 12 and located under the scissors member 112 for returning the keycap 111 to the original position. When the key 11 is depressed, the keycap 111 is moved downwardly to press the rubbery elastomer 113 so as to result in deformation of the rubbery elastomer 113. Moreover, the circuit board 12 is pressed by the rubbery elastomer 113 so as to generate a key signal. When the key 11 is no longer depressed, the rubbery elastomer 113 is restored to the original shape. Consequently, the keycap 111 is moved upwardly in the direction away from the base plate 13.

As mentioned above, the rubbery elastomer 113 of the keyboard device 10 can provide the hand feed of pressing the key 11 to the user. Moreover, when the key 11 is no longer depressed by the user, the rubbery elastomer 113 can allow the keycap 111 of the key 11 to be returned to the original position. However, since the rubbery elastomer 113 has certain height and volume, the arrangement of the rubbery elastomer 113 may increase the overall height of the keyboard device 10. Under this circumstance, it is difficult for the user to carry the keyboard device 10.

In other words, it is an important issue to provide a keyboard device with slimness and hand feel. Therefore, there is a need of providing an improved keyboard device in order to overcome the above drawbacks.

### SUMMARY OF THE INVENTION

An object of the present invention provides a slim-type keyboard device.

In accordance with an aspect of the present invention, there is provided a keyboard device. The keyboard device includes a base plate, a circuit board and plural keys. The circuit board is disposed on the base plate. The plural keys are disposed on the circuit board. Each of the plural keys includes a keycap, a scissors member, a restoring element and a sensor. The scissors member is arranged between the keycap and the base plate and connected with the keycap and the base plate. The restoring element is arranged between the keycap and the base plate and electrically connected with the circuit board to receive electricity from the circuit board. When the electricity is received by the restoring element, the restoring element is subjected to deformation to move the keycap away from the base plate. The sensor is disposed under the restoring element and electrically connected with the circuit board. When the sensor is triggered, a key signal is generated. When the keycap is depressed and close to the base plate, the restoring element is pressed by the keycap to trigger the sensor to generate the key signal. When the keycap is no longer depressed, the keycap is driven by the restoring element so as to be moved away from the base plate.

In an embodiment, the sensor is disposed on the circuit board, and the restoring element is located over the sensor.

In an embodiment, the circuit board includes plural openings, wherein each restoring element and the corresponding sensor are disposed within the corresponding opening.

In an embodiment, the restoring element is made of electroactive polymer (EAP).

In an embodiment, the keycap further includes a protrusion. The protrusion is disposed on a bottom surface of the keycap and contacted with the restoring element. When the keycap is depressed, the restoring element is pressed by the protrusion of the keycap.

In an embodiment, when the electricity is not received by the restoring element, the restoring element has a flat rectangular shape, wherein when the electricity is received by the restoring element, the restoring element has a cambered rectangular shape.

In an embodiment, each keycap includes plural first fixing parts, and the base plate comprises plural second fixing parts. The scissors member is fixed on the base plate through the plural first fixing parts and the plural second fixing parts.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic view illustrating a conventional keyboard device;

FIG. 2 is a schematic perspective view illustrating a keyboard device according to a first embodiment of the present invention;

FIG. 3 is a schematic exploded view illustrating a key according to a first embodiment of the present invention;

FIG. 4 schematically illustrates the key according to the first embodiment of the present invention, in which no electricity is received by the restoring element;

FIG. 5 schematically illustrates the key according to the first embodiment of the present invention, in which the electricity is received by the restoring element;

FIG. 6 schematically illustrates the key according to the first embodiment of the present invention, in which the key is depressed;

FIG. 7 is a schematic exploded view illustrating a key according to a second embodiment of the present invention;

FIG. 8 schematically illustrates the key according to the second embodiment of the present invention, in which no electricity is received by the restoring element; and

FIG. 9 schematically illustrates the key according to the second embodiment of the present invention, in which the electricity is received by the restoring element.

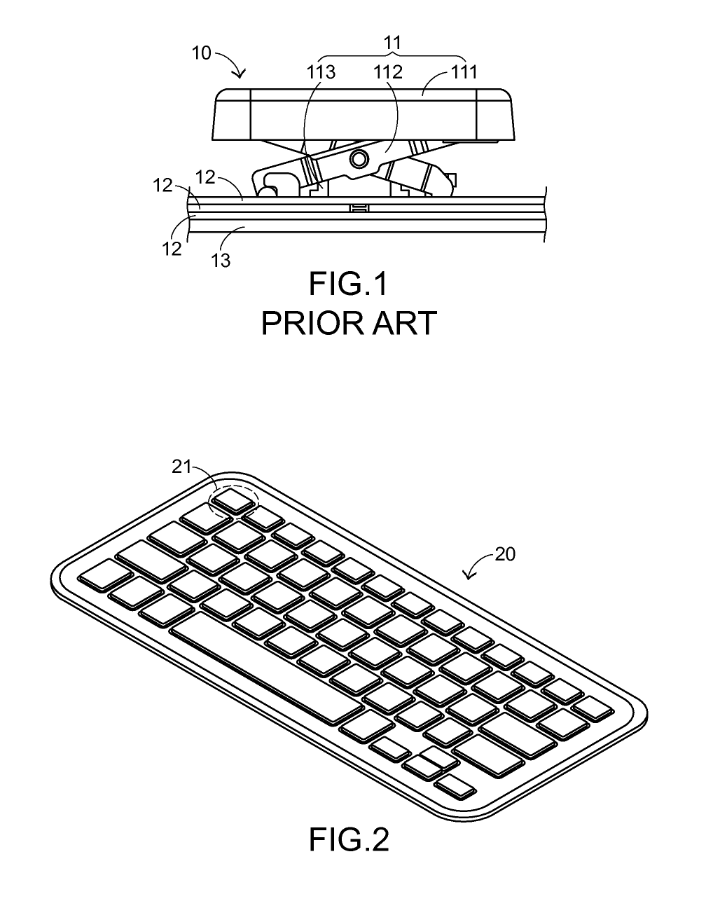

### DETAILED DESCRIPTION OF THE PREFERRED EMBODIMENT

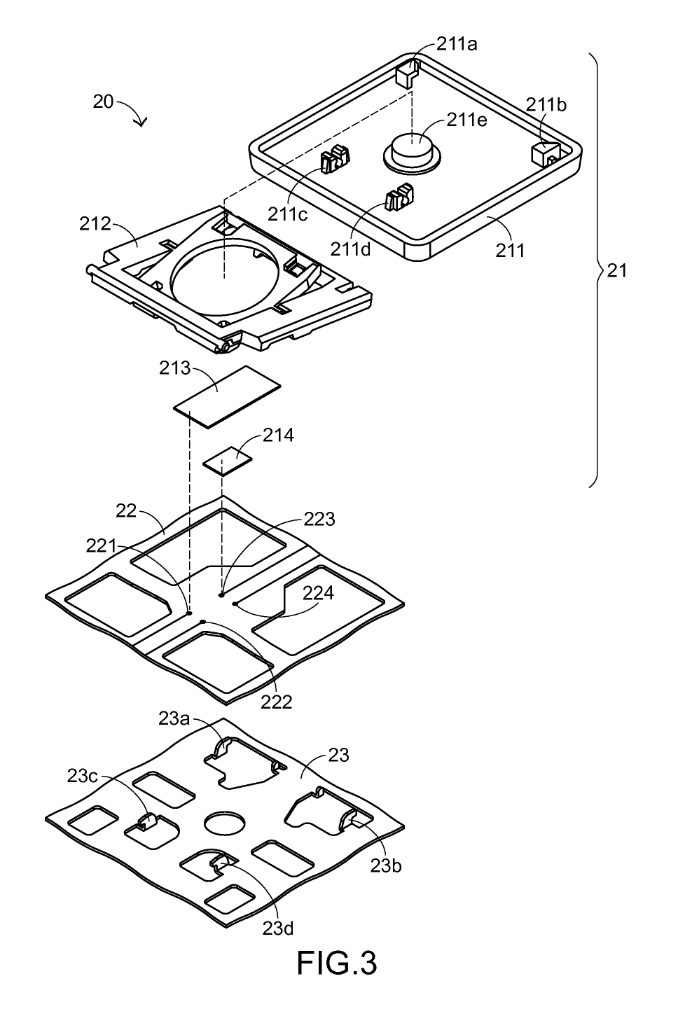

Please refer to FIGS. 2 and 3. FIG. 2 is a schematic perspective view illustrating a keyboard device according to a first embodiment of the present invention. FIG. 3 is a schematic exploded view illustrating a key according to a first embodiment of the present invention. As shown in FIGS. 2 and 3, the keyboard device 20 comprises plural keys 21, a circuit board 22 and a base plate 23. The circuit board 22 comprises a first electrical contact 221, a second electrical contact 222, a third electrical contact 223 and a fourth electrical contact 224. The plural keys 21 are disposed on the circuit board 22. When one of the plural keys 21 is depressed by the user, a corresponding key signal is generated. Moreover, the plural keys 21 and the circuit board 22 are all disposed on the base plate 23. The base plate 23 is a plate made of a metallic material, a plastic material or any other appropriate material. The base plate 23 is used for supporting the plural keys 21 and the circuit board 22. An example of the keyboard device 20 includes but is not limited to a wired keyboard device or a wireless keyboard device.

Please refer to FIG. 3 again. Each key 21 comprises a keycap 211, a scissors member 212, a restoring element 213 and a sensor 214. The keycap 211 comprises plural first fixing parts 211a, 211b, 211c and 211d and a protrusion 211e. The base plate 23 comprises plural second fixing parts 23a, 23b, 23c and 23d. The plural first fixing parts 211a, 211b, 211c and 211d are disposed on a bottom surface of the keycap 211. The plural second fixing parts 23a, 23b, 23c and 23d are disposed on a top surface of the base plate 23. In this embodiment, the keycap 211 is made of a plastic material. Preferably but not exclusively, the plural first fixing parts 211a, 211b, 211c and 211d and the protrusion 211e are integrally formed on the bottom surface of the keycap 211 by an ejection molding process.

The scissors member 212 is arranged between the keycap 211 and the base plate 23 for connecting the keycap 211 and the base plate 23. That is, the keycap 211 is fixed on the base plate 23 through the scissors member 212. For example, the top ends and the bottom ends of the scissors member 212 have plural locking parts. The locking parts at the top ends of the scissors member 212 are connected with the plural first fixing parts 211a, 211b, 211c and 211d of the keycap 211, and the locking parts at the bottom ends of the scissors member 212 are connected with the plural second fixing parts 23a, 23b, 23c and 23d of the base plate 23. When the plural locking parts of the scissors member 212 are connected with the plural first fixing parts 211a, 211b, 211c and 211d and the plural second fixing parts 23a, 23b, 23c and 23d, the scissors member 212 is fixed on the base plate 23 and the keycap 211 is fixed on the scissors member 212. Consequently, the keycap 211 is fixed on the base plate 23. The structures of the scissors member 212 of the present invention are substantially identical to those of the conventional scissors member, and are not redundantly described herein.

The restoring element 213 is arranged between the keycap 211 and the base plate 23 for returning the keycap 211 to its original position. In particular, the restoring element 213 is disposed on the circuit board 22, and electrically connected with the first electrical contact 221 and the second electrical contact 222 of the circuit board 22 so as to acquire electricity from the circuit board 22. In this embodiment, the restoring element 213 is made of electroactive polymer (EAP). In case that no electricity is received by the restoring element 213, the restoring element 213 has a flat rectangular shape. Whereas, in case that the electricity is received by the restoring element 213, the restoring element 213 has a cambered rectangular shape. Consequently, when the electricity is received by the restoring element 213, the keycap 211 is moved away from the base plate 23 in response to the deformation of the restoring element 213.

The sensor 214 is disposed under the restoring element 213. Moreover, the sensor 214 is disposed on the circuit board 22, and electrically connected with the third electrical contact 223 and the fourth electrical contact 224 of the circuit board 22. When the electricity from the circuit board 22 is received by the sensor 214, the sensor 214 is enabled to sense whether the keycap 211 is depressed. When the keycap 211 is depressed, the sensor 214 generates the key signal. In addition, the key signal is transmitted through the circuit board 22 to the electronic device that is controlled by the keyboard device 20. For example, the electronic device controlled by the keyboard device 20 includes a desktop computer, a notebook computer, a tablet computer or a smart phone.

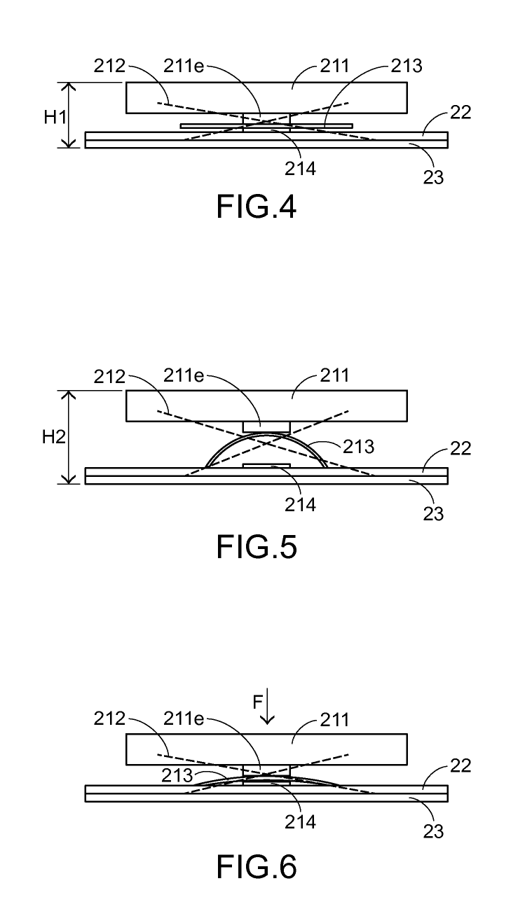

The operations of the key 21 will be illustrated with reference to FIGS. 4, 5 and 6. FIG. 4 schematically illustrates the key according to the first embodiment of the present invention, in which no electricity is received by the restoring element. FIG. 5 schematically illustrates the key according to the first embodiment of the present invention, in which the electricity is received by the restoring element. FIG. 6 schematically illustrates the key according to the first embodiment of the present invention, in which the key is depressed. As shown in FIG. 4, the keyboard device 20 is not electrically connected with the electronic device or a power switch of the keyboard device 20 is not turned on. Since no electricity is received by the restoring element 213, the restoring element 213 has the flat rectangular shape. Meanwhile, the distance between the keycap 211 and the bottom and the base plate 23 is equal to a first height H1.

When the keyboard device 20 is electrically connected with the electronic device (e.g., a computer) or the power switch of the keyboard device 20 is turned on, the electricity from the circuit board 22 is transmitted to the power consumption components of the keyboard device 20. For example, the power consumption components include the restoring element 213 and the sensor 214. As shown in FIG. 5, the restoring element 213 receives the electricity. Consequently, the restoring element 213 is subjected to deformation, and the restoring element 213 is switched from the flat rectangular shape to the cambered rectangular shape. Under this circumstance, the scissors member 212 is in an open-scissors state. Meanwhile, the distance between the keycap 211 and the bottom and the base plate 23 is increased to a second height H2.

Then, as shown in FIG. 6, an external force F is applied to the keycap 211 of the key 21. In response to the external force F, the keycap 211 is moved downwardly. As the keycap 211 is moved downwardly, the protrusion 211e is contacted with the restoring element 213 to press the restoring element 213. Consequently, the sensor 214 is triggered to generate the key signal. Preferably but not exclusively, the sensor 214 is a membrane switch circuit, a capacitive sensor or any other appropriate sensor. For example, if the sensor 214 is the membrane switch circuit, the depressed restoring element 213 is contacted with the sensor 214 to push the sensor 214. Consequently, the circuitry of the sensor 214 is electrically conducted to generate the key signal. If the sensor 214 is the capacitive sensor and the depressed restoring element 213 is close to the sensor 214, the sensor 214 senses the change of the capacitance value. According to the change of the capacitance value, the key signal is generated.

When the keycap 211 is no longer depressed by the user, the shape of the restoring element 213 is restored to the cambered rectangular shape (see FIG. 5) because the electricity is still received by the restoring element 213. By means of the restoring element 213, the keycap 211 is returned to the original position, so that the distance between the keycap 211 and the bottom and the base plate 23 is increased to the second height H2 again. Consequently, the keycap 211 is moved away from the base plate 23. Similarly, when the external force F is applied to the keycap 211 of the key 21 again, the keycap 211 is moved downwardly again (see FIG. 6). Consequently, the sensor 214 is triggered to generate the key signal.

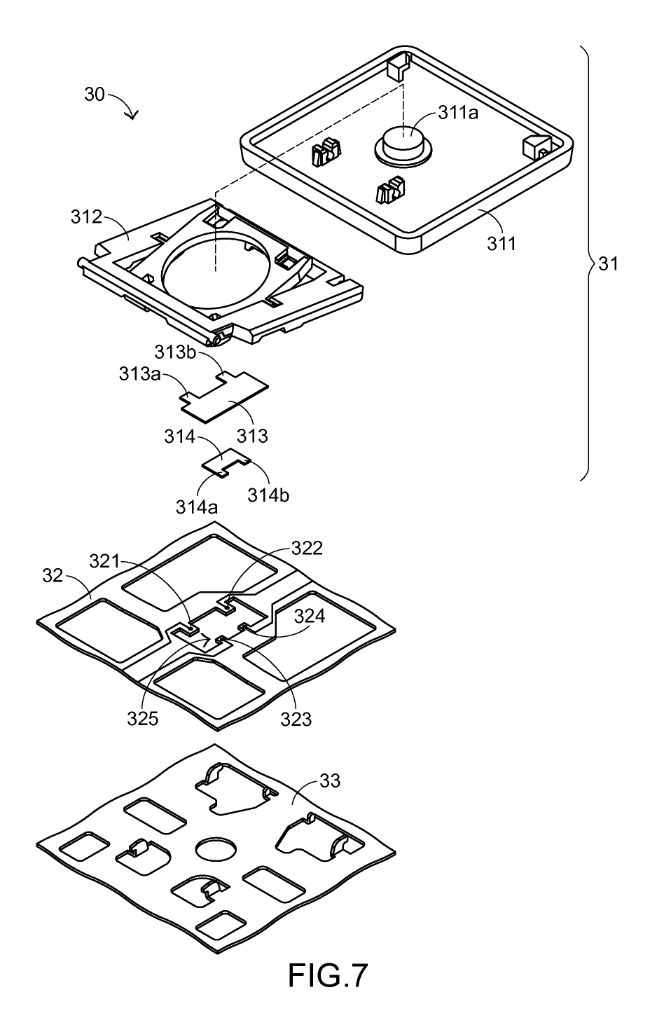

The present invention further provides a key according to a second embodiment of the present invention. FIG. 7 is a schematic exploded view illustrating a key according to a second embodiment of the present invention. As shown in FIG. 7, the keyboard device 30 comprises plural keys 31, a circuit board 32 and a base plate 33. The circuit board 32 comprises a first electrical contact 321, a second electrical contact 322, a third electrical contact 323 and a fourth electrical contact 324. The plural keys 31 are disposed on the circuit board 32. When one of the plural keys 31 is depressed by the user, a corresponding key signal is generated. Moreover, the plural keys 31 and the circuit board 32 are all disposed on the base plate 33. Each key 31 comprises a keycap 311, a scissors member 312, a restoring element 313 and a sensor 314. Moreover, a protrusion 311a is disposed on a bottom surface of the keycap 311.

The scissors member 312 is arranged between the keycap 311 and the base plate 33 for connecting the keycap 311 and the base plate 33. The way of fixing the keycap 311 on the base plate 33 through the scissors member 312 is similar to that of the first embodiment as shown in FIG. 3, and is not redundantly described herein. Moreover, the restoring element 313 is arranged between the keycap 311 and the base plate 33, and the sensor 314 is disposed under the restoring element 313. The restoring element 313 is used for returning the keycap 311 to its original position. The sensor 314 is used for generating the key signal.

The restoring element 313 and the sensor 314 are electrically connected with the circuit board 32. In this embodiment, the restoring element 313 comprises a first coupling part 313a and a second coupling part 313b. The first coupling part 313a and the second coupling part 313b of the restoring element 313 are electrically connected with the first electrical contact 321 and the second electrical contact 322 of the circuit board 32, respectively. Consequently, the restoring element 313 can acquire electricity from the circuit board 32. The sensor 314 comprises a third coupling part 314a and a fourth coupling part 314b. The third coupling part 314a and the fourth coupling part 314b of the sensor 314 are electrically connected with the third electrical contact 323 and the fourth electrical contact 324 of the circuit board 32, respectively. Consequently, the sensor 314 can acquire electricity from the circuit board 32. Through the circuit board 32, the generated key signal is transmitted to the electronic device that is controlled by the keyboard device 30.

In this embodiment, the restoring element 313 is made of electroactive polymer (EAP). In case that no electricity is received by the restoring element 313, the restoring element 213 has a flat rectangular shape. Whereas, in case that the electricity is received by the restoring element 313, the restoring element 313 is subjected to deformation, and the restoring element 313 is switched from the flat rectangular shape to a cambered rectangular shape. Consequently, when the electricity is received by the restoring element 313, the keycap 311 is moved away from the base plate 33 in response to the deformation of the restoring element 313.

In comparison with the keyboard device 20 of FIG. 3, the circuit board 32 of the keyboard device 30 of this embodiment has plural openings 325, and both of the restoring element 313 and the sensor 314 are disposed within the corresponding opening 325 of the circuit board 32. The other components of the keyboard device 30 of this embodiment are substantially identical to those of the keyboard device 20 of the first embodiment, and are not redundantly described herein. Since both of the restoring element 313 and the sensor 314 are disposed within the corresponding opening 325 of the circuit board 32, the height between the keycap 311 and the base plate 33 is further reduced. Consequently, the slimness efficacy of the keyboard device 30 is enhanced.

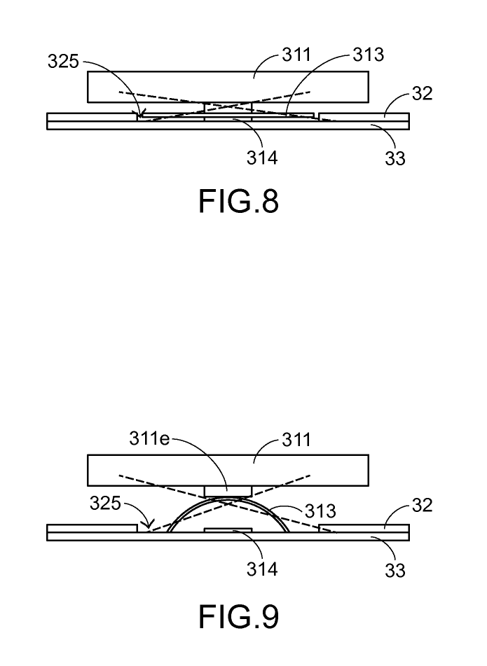

Please refer to FIGS. 8 and 9. FIG. 8 schematically illustrates the key according to the second embodiment of the present invention, in which no electricity is received by the restoring element. FIG. 9 schematically illustrates the key according to the second embodiment of the present invention, in which the electricity is received by the restoring element. As shown in FIG. 8, the circuit board 32 is disposed on the base plate 33, and the restoring element 313 and the sensor 314 are disposed within the opening 325 of the circuit board 32. As shown in FIG. 9, the restoring element 313 receives the electricity from the circuit board 32. Since the electricity is received by the restoring element 313, the restoring element 313 is subjected to deformation, and the restoring element 313 is switched from the flat rectangular shape to the cambered rectangular shape. Under this circumstance, the scissors member 312 is in an open-scissors state. Meanwhile, the distance between the keycap 311 and the bottom and the base plate 33 is increased. In case that the keycap 311 of the key 31 is depressed by the user, the keycap 311 is moved downwardly. As the keycap 311 is moved downwardly, the protrusion 311a is contacted with the restoring element 313 to press the restoring element 313. Consequently, the sensor 314 is triggered to generate a key signal.

From the above descriptions, the present invention provides the keyboard device. When the electricity is received by the restoring element, the restoring element is subjected to deformation to move the keycap away from the base plate. Consequently, the keycap can be returned to its original position. In comparison with the conventional keyboard device using the rubbery elastomer as the restoring element, the height of the restoring element of the keyboard device is smaller than the height of the rubbery elastomer. Consequently, the overall height of the keyboard device of the present invention is reduced. Moreover, since the restoring element of the present invention results in the deformation when receiving the electricity, the restoring element has the restoring function. In case that the keyboard device of the present invention is not electrically connected with the electronic device or the power switch of the keyboard device is not turned on, no electricity is received by the restoring element, so that the restoring element has the flat rectangular shape. Consequently, the overall height of the keyboard device of the present invention is further reduced. That is, since the keyboard device of the present invention is slimmer and lighter, the keyboard device can be carried more easily.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A keyboard device, comprising:
a base plate;
a circuit board disposed on the base plate; and
plural keys disposed on the circuit board, wherein each of the plural keys comprises:
a keycap;
a scissors member arranged between the keycap and the base plate and connected with the keycap and the base plate;
a restoring element arranged between the keycap and the base plate and electrically connected with the circuit board to receive electricity from the circuit board, wherein when the electricity is received by the restoring element, the restoring element is subjected to deformation to move the keycap away from the base plate; and
a sensor disposed under the restoring element and electrically connected with the circuit board, wherein when the sensor is triggered, a key signal is generated,
wherein when the keycap is depressed and close to the base plate, the restoring element is pressed by the keycap to trigger the sensor to generate the key signal, wherein when the keycap is no longer depressed, the keycap is driven by the restoring element so as to be moved away from the base plate.

2. The keyboard device according to claim 1, wherein the sensor is disposed on the circuit board, and the restoring element is located over the sensor.

3. The keyboard device according to claim 1, wherein the circuit board comprises plural openings, wherein each restoring element and the corresponding sensor are disposed within the corresponding opening.

4. The keyboard device according to claim 1, wherein the restoring element is made of electroactive polymer (EAP).

5. The keyboard device according to claim 1, wherein the keycap further comprises a protrusion, wherein the protrusion is disposed on a bottom surface of the keycap and contacted with the restoring element, wherein when the keycap is depressed, the restoring element is pressed by the protrusion of the keycap.

6. The keyboard device according to claim 1, wherein when the electricity is not received by the restoring element, the restoring element has a flat rectangular shape, wherein when the electricity is received by the restoring element, the restoring element has a cambered rectangular shape.

7. The keyboard device according to claim 1, wherein each keycap comprises plural first fixing parts, and the base plate comprises plural second fixing parts, wherein the scissors member is fixed on the base plate through the plural first fixing parts and the plural second fixing parts.
